(19) United States
(12) Patent Application Publication
(10) Pub. No.: US 2025/0184453 A1
(43) Pub. Date: Jun. 5, 2025

(54) METHOD AND APPARATUS FOR MONITORING AN INDUSTRIAL PLANT

(71) Applicant: BASF SE, Ludwigshafen Am Rhein (DE)

(72) Inventors: Katharina HACK, Ludwigshafen am Rhein (DE); Benjamin PRIESE, Ludwigshafen am Rhein (DE); Volker HILDEBRANDT, Ludwigshafen am Rhein (DE)

(21) Appl. No.: 18/845,016

(22) PCT Filed: Mar. 23, 2023
(86) PCT No.: PCT/EP23/57499

§ 371 Date: Sep. 9, 2024

(30) Foreign Application Priority Data
Mar. 23, 2022 (EP) 22163906.5

(51) Int. Cl. H04N 7/18; G06V 10/74; G06V 20/40; G06V 20/52

(52) U.S. Cl. CPC H04N 7/181; G06V 10/74; G06V 20/48; G06V 20/52

(57) ABSTRACT

Disclosed herein is a method for monitoring an industrial plant including plant objects, where the following steps are carried out: receiving (S1) a video stream (VS) of the plant generated with the aid of a video camera device; assigning (S2) two-dimensional image components (PT) of the video stream (VS) to plant objects (A′, B′, C′, D′) with the aid of a three-dimensional (3D) model (CAD) of the plant; determining (S3) a recording property of the image data depending on the image components (PT) assigned to one or more plant objects (C′) and the respective object property (XYZ); and outputting (S4) the video stream (VS′) together with the determined object properties (XYZ) and/or recording properties. Further disclosed herein are a computer program product and an apparatus.

The present invention relates to a method and an apparatus for observing or monitoring an industrial plant. Furthermore, a computer program product is proposed which functionalizes program-controllable devices in such a way that they carry out a method for monitoring an industrial plant.

In general, industrial plants such as factories, in particular pertaining to the chemical industry, distribution systems for raw materials or processed products, but also logistical industrial systems are visually monitored or recorded with the aid of video cameras. In order to reliably monitor the plant objects of an industrial plant that interact complexly with one another, it is customary to use many monitoring cameras which monitor a respective spatial region and provide video streaming data.

It is desirable to be able to reliably evaluate such real-time video data and to be able to intervene if the plant behavior exhibits irregularities. In the past, video camera devices have been arranged in a manner distributed over spatial regions to be monitored, and for example have been pivotably mounted or provided with a zoom function. The generated video streams have often encompassed no information over and above the video data, and so the specific location of the monitoring camera which supplies the video stream or the settings of this camera has/have remained unknown. In the past, therefore, monitoring of the displayed videos or films has been performed, in particular manually.

It is desirable to simplify in particular the visual monitoring of industrial plants with the aid of video streams. In particular, it is desirable to provide information over and above the image data or video sequences. In general, exclusively image data are available in already installed monitoring systems of industrial plants.

The assignment of two-dimensional image data components of industrial plants to existing three-dimensional (3D) plant models is described in N. Navab et al.: “Cyclicon: a software platform for the creation and update of virtual factories”, 1999 IEEE, pages 459-463, 1999 7th IEEE International Conference on Emerging Technologies and Factory Automation. Proceedings ETFA ′99, ISBN: 0-7803-5670-5. Cyclicon here allows the superimposed representation of two-dimensional projections of the three-dimensional plant model on the two-dimensional image data. However, this requires the prior assignment of the known configuration of the monitoring camera to specific 3D model data, and vice versa. Moreover, the user may be requested to mark specific predefined image points in the 2D image data in order that the superimposition of the video stream can take place.

In the prior art, a necessary prerequisite for image analysis is that the origin and the contextual content of the two-dimensional image data are predefined. This is generally not the case in practice because, in particular, there are a large number of video streams from different cameras, the recording settings, orientations and further properties of which are undocumented. Moreover, the cameras are often not fixed, but rather can be rotated. A manual annotation of the video stream data by the user with the video stream running is practically impossible as a result.

Against this background, it is an object of the present invention to provide an improved method for monitoring industrial plants, in particular with many video camera devices and plant objects.

Accordingly, a method for monitoring an industrial plant comprising plant objects is proposed which comprises the following steps:
receiving a video stream of the plant generated with the aid of a video camera device, wherein the video stream comprises a temporal sequence of two-dimensional image data;
assigning two-dimensional image components of the video stream to plant objects with the aid of a three-dimensional model of the plant, in which respective object properties are allocated to the plant objects;
determining a recording property of the image data depending on the image components assigned to one or more plant objects and the respective object property, wherein the recording property comprises a position, an orientation and/or a zoom factor of the video camera device which captures the video stream; and outputting the video stream together with the determined object properties and/or recording properties.

Receiving the video stream takes place in particular at a monitoring location remote from the position of the video camera device. In this respect, the video camera device is mounted at an unknown position during the step of receiving the video stream. At the monitoring location, the recording properties are not directly observable, but rather are advantageously derived from the two-dimensional image components and the three-dimensional model of the plant.

The method steps, in particular those of assigning and determining, are preferably carried out in an automated manner. The carrying out in an automated manner can take place in a computer-implemented manner in the background, without a user explicitly calling up the recording properties and object properties.

An industrial plant is understood to mean, in particular, a system of technical facilities which interact with one another and serve for example for manufacturing, processing or relaying of substances. The technical facilities can be understood as plant objects or plant parts. By way of example, an infrastructure plant for water and/or wastewater, recooling plants, electrical distribution facilities, fuel depots and supply facilities is/are suitable as an industrial plant. In embodiments, the monitored industrial plant is a plant pertaining to the chemical industry.

In the method, from the image data obtained from a video camera device, such as a digital monitoring camera, or a video stream comprising a temporal sequence of two-dimensional image data, a respective piece of context information in relation to the camera and/or the plant object captured in the video stream is ascertained. By virtue of outputting the video stream and/or a two-dimensional image together with the determined object or recording properties, it is possible to categorize a state of the monitored industrial plant in an improved manner.

A recording property is understood to mean, in particular, a property which is assignable to the video stream or to an individual two-dimensional image datum and which depends on the creation of the respective image. This may be for example an image angle, an excerpt, a recording position and orientation of the video camera device. Exposure settings are also conceivable as recording property. Camera properties may also be a term employed.

It is also possible for environmental conditions, such as light, dark, weather conditions and the like, to be taken into account in the determination of the recording property.

The image component may be, for example, an image excerpt from the overall image or an image data set created by means of filtering.

A three-dimensional plant model like a CAD model can be used, for example, in which the plant objects, i.e. the components of the industrial plant, are provided with known object properties. Suitable object properties include, in particular, a location, a size or a dimension, the alignment or orientation and a list of subcomponents or material properties and surface properties of the respective plant object. Furthermore, conceivable object properties include a list of assignable static or dynamic data, such as, for example, but not exclusively, material and design details, flow media and parameters, such as substance, flow rate, temperature, pressure or manipulated and controlled variables of fittings.

The position, orientation or the zoom factor of the respective video camera device can be deduced by an, in particular computer-implemented, evaluation of two-dimensional image components. That is to say that, with the aid of the proposed method, from the obtained two-dimensional image data sequences in the manner of the video stream using a suitable three-dimensional model of the industrial plant, recording conditions or the video camera device directed at the image component or a specific plant object can be characterized more specifically as recording properties. The recording properties regarding the orientation, i.e. the direction in which the monitoring camera is facing, and the capturable image angle or the currently set zoom factor of the monitoring camera are obtained without additional data to be gathered. The orientation can be specified in a local or global coordinate system.

In embodiments, the one or multiple video camera device(s) has/have a video capture region. The video capture region comprises spatial surroundings of the respective video camera device and is defined for example by the camera properties, such as its capture angles, panning possibilities, zoom possibilities, resolution, light sensitivity and the like. In the case of a fixedly installed video camera device with a fixed focus and zoom, the video stream obtained in the by the video camera device shows a fixed image excerpt, which in this respect forms the video capture region of the surroundings.

In embodiments, the industrial plant is arranged on a spatial site or a plant site. In general, the respective video capture region is smaller than the plant site. By way of example, only a large number of partly overlapping video capture regions of a plurality of video camera devices cover the plant site. In embodiments, the video capture regions are on the plant site, but can be situated independently of one another or can be spatially separated by non-monitored regions.

In embodiments, the video camera device is arranged on the plant site, and the three-dimensional model of the plant comprises the, in particular entire, plant site. The step of determining a recording property then preferably comprises: determining the position of the video camera device within the plant site and with further preference within the video capture region.

In embodiments, the position of the video camera device in the global and/or the local coordinate system is output.

The global coordinate system can be relative to the plant site, and the local coordinate system to the respective video capture region. In environments, the three-dimensional model of the plant covers the plant site in the global coordinate system, and the position of the video camera device is ascertained in the global coordinate system, preferably also in the local coordinate system. In this respect, the video capture region preferably covers the local coordinate system.

An observation or monitoring of the plant is thus improved. If an event occurs, such as an accident, for example, the scene of the accident can be determined and reached more quickly and more easily by personnel. The automated supplementation of recording and/or object data that are not derivable from the video stream alone facilitates the evaluation of the current plant state or the current situation. This can serve for managing an accident but also generally for assessment, optimization and facilitated operator control during plant operation.

In embodiments, the monitoring camera itself is captured as a part of the plant, i.e. as plant object in the 3D model. It is possible that in any case the location or the position of the respective camera is known and is used for determining the orientation and the zoom factor.

Advantageously, the video stream is output together with the object or recording properties, such that comprehensive image information can be specified for example in a mobile terminal comprising a display apparatus or a control console for monitoring the industrial plants.

In this respect, in embodiments, the video stream is represented together with the object properties and the recording properties with the aid of a display device.

Monitoring a plant is also understood to mean, in particular, observation, evaluation and optimization by way of improved provision of information. In this respect, capturing or deriving information about the “monitored” plant with the aid of video stream data is regarded as monitoring.

In embodiments of the method, the following step is carried out: creating a database which assigns further functional properties and/or context data to the plant objects. The functional properties comprise for example process data, temperatures or flow materials. In embodiments, the context data can comprise in particular time data, weather data and/or visibility conditions. The assignable static or dynamic data mentioned above are suitable as context data.

The database can be linked with the three-dimensional model of the plant, in particular, such that the respective recorded plant object can be identified from an image component with the aid of the three-dimensional model data and the functional properties. Particularly on the basis of the identification of plant objects in image components and also the object properties stored in the 3D model, such as a size, positioning or orientation, it is possible to determine the camera position, the orientation thereof and/or the zoom factor.

In particular, image processing methods as mentioned in the introduction are suitable here. In embodiments of the method, the functional properties and/or the context data are updated in real time, in particular.

In the method, a dynamic recording property can be determined for example with the aid of a temporal sequence of two-dimensional image components of the video stream. It is conceivable to capture a camera movement or zoom speed, which is output as a recording property.

In embodiments of the method, an orientation or a zoom factor of the respective video camera device which supplies the video stream data is altered depending on the dynamic or statically captured recording properties, in particular in an automated manner.

In embodiments of the method, the video stream does not comprise information data about the recording properties. In this respect, preferably, the recording property is ascertained exclusively by way of a comparison of the assigned two-dimensional image components with the data of the 3D model. In embodiments, the three-dimensional model data regarding the industrial plant can comprise a position of the video camera device or devices.

In embodiments, a zoom factor of the video camera device is ascertained depending on a plurality of temporally successive two-dimensional image data of the video camera device.

By way of comparing a plurality of temporally successive image data and the object properties present in the three-dimensional model, a zoom factor or else the zoom speed can be ascertained in this respect.

In embodiments, the method comprises at least one of the following steps:
transmitting the video stream to a processing platform;
transmitting the 3D model to the processing platform; and
transmitting the determined recording property from the processing platform to a display device.

Preferably, the processing platform is designed like a cloud service. The processing platform can then be configured to carry out the steps of assigning two-dimensional image components and determining the respective recording property in a computer-implemented manner in a secure processing environment.

The processing platform can be implemented for example with the aid of a Microsoft Azure environment or else by way of web services of other providers, such as AWS, for example. The respective data are preferably transmitted by means of secure and cryptographically protected communication protocols.

In embodiments, the processing platform is designed like an app that runs on a terminal, such as a smartphone or tablet computer, for example. The processing platform is then configured to carry out the steps of assigning two-dimensional image components and determining the respective recording property in a computer-implemented manner in a secure processing environment of the terminal.

In embodiments, the method comprises: receiving a plurality of video streams from different video camera devices.

The steps of assigning two-dimensional image components, determining a respective recording property and outputting the video stream preferably take place for each video stream and the associated video camera device in each case using the respective 3D model for the respective industrial plant or the plant part. The same 3D model can be used in embodiments, and different 3D models are used in other embodiments.

The video camera devices capture in particular different regions of the industrial plant, such that a capture direction of the respective two-dimensional image component of the respective video stream is defined depending on the orientation, positioning and the zoom setting of a respective video camera. In this respect, an additional context like the recording property or the object properties can be added to each video stream. A superimposed representation of the video stream images and the additional properties is conceivable. Additional properties are understood to be, in particular, the camera data and the object data.

Embodiments comprise optionally forwarding one of a plurality of video streams to a processing platform designed like a cloud service.

Furthermore, an apparatus for carrying out the method for monitoring an industrial plant described above and below is proposed. An apparatus comprises, in particular:
a video camera device for generating the video stream of the industrial plant;
a storage device for providing the three-dimensional model of the plant, in which respective object properties are allocated to the plant objects;
a processing device for assigning two-dimensional image components of the video stream to plant objects with the aid of the 3D model, and for determining the recording property; and/or
a display device for outputting the video stream together with the determined object properties and/or recording properties, in particular as a superimposition, and an assignment to the 3D model.

In this case, the video camera device, the storage device, the processing device and the display device are preferably communicatively coupled to one another. The functions of the processing device can be provided by software services in a cloud environment.

A respective method step or a functionalized device, for example a processor unit or processing device, can be implemented in terms of hardware and/or else in terms of software. In the case of an implementation in terms of hardware, the respective function can be embodied as an apparatus or as part of an apparatus, for example as a computer or as a microprocessor. In the case of an implementation in terms of software, the respective unit can be embodied as a computer program product, as an app, as a function, as a routine, as part of a program code or as an executable object, in particular as a software service in a cloud environment.

Furthermore, a computer program product is proposed which comprises computer-readable instructions which, when the program is executed by a computer, cause the latter to execute the method described above. A computer program product comprises in particular machine-readable instructions which, when they are processed by one or more processor devices of a processing environment, cause one or all method steps of the proposed method to be carried out.

A computer program product, such as e.g. a computer program means, can be provided or supplied for example as a storage medium, such as e.g. memory card, USB stick, CD-ROM, DVD, or else in the form of a downloadable file from a server in a network. This can take place for example in a wireless communication network by way of the transmission of a corresponding file comprising the computer program product or the computer program means.

The embodiments and features described for the proposed apparatus apply, mutatis mutandis, to the proposed method.

Further possible implementations of the invention also comprise not explicitly mentioned combinations of features or embodiments described above or below with regard to the examples. In this case, the person skilled in the art will also add individual aspects as improvements or supplementations to the respective basic form of the invention.

Further advantageous configurations and aspects of the invention are the subject matter of the dependent claims and of the examples of the invention described below. The invention is explained in greater detail below on the basis of preferred embodiments with reference to the accompanying figures.

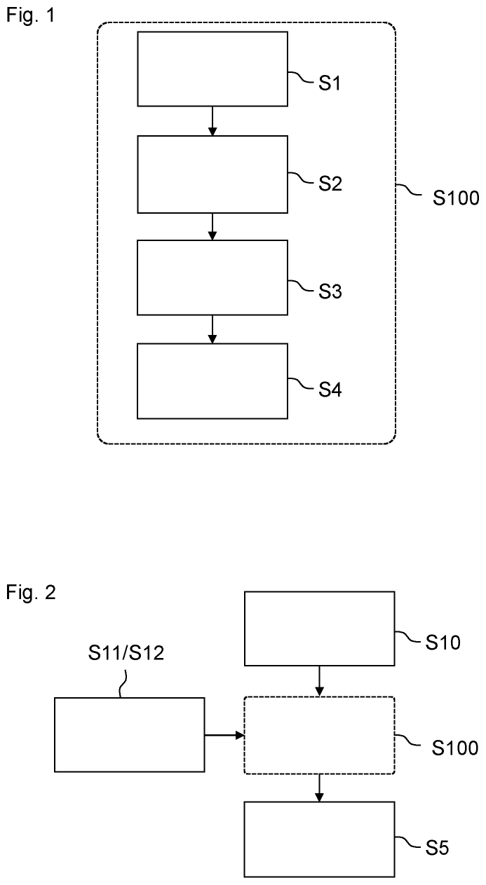

FIG. 1 shows a flow diagram with method steps for one variant of a method for monitoring an industrial plant;

FIG. 2 shows an extended flow diagram with method steps for a further variant of a method for monitoring an industrial plant;

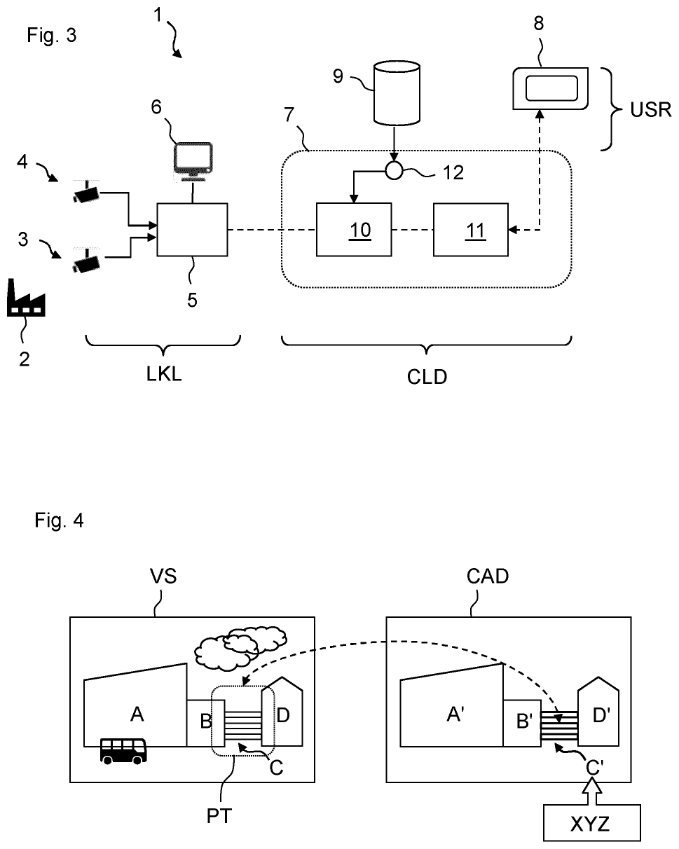

FIG. 3 diagrammatically shows one embodiment of an apparatus for monitoring an industrial plant;

FIG. 4 diagrammatically shows a video stream and an assignment of image components to plant objects for elucidating the method for monitoring an industrial plant; and

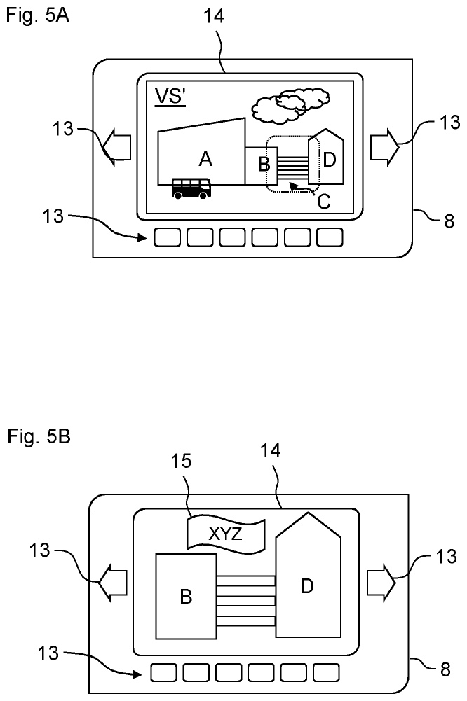

FIG. 5 shows one embodiment of a display device.

In the figures, identical or functionally identical elements have been provided with the same reference signs, unless indicated otherwise.

FIGS. 1 and 2 illustrate flow diagrams with method steps for an example of a method for monitoring an industrial plant. The method steps are performed in particular in an embodiment of an apparatus for monitoring an industrial plant as shown diagrammatically in FIG. 3.

In this respect, FIG. 3 shows a monitoring system or an apparatus 1 for an industrial plant 2, which may be for example a complex pipeline system, a factory, refinery, production line or else a logistics facility. A plant 2 geographically occupying an extensive spatial region can be captured by means of one or more monitoring cameras 3, 4 designed as digital video cameras. In this case, video stream data are generated in real time, in particular. The video cameras 3, 4 used may in this case be arranged at different positions in the region of the plant 2 and may be for example pivotably or else fixedly oriented. It is also conceivable for different cameras to be equipped with an optical zoom. This results in video streams showing different image excerpts that reproduce parts or objects of the plant 2.

The video stream data, represented as arrows toward the right in FIG. 3, are communicated to a local computing device 5, for example a control console. The video data supplied by the installed camera systems do not comprise information about the respective orientation, the zoom factor or, for example, focus settings of the cameras 3, 4.

In FIG. 4, by way of example, a frame of a video stream VS is indicated diagrammatically on the left-hand side. In this case, the industrial plant 2 is indicated in a simplified manner with four plant objects A, B, C, D. The video stream VS furthermore comprises a representation of the surroundings of the industrial plant. It is then possible for one of the video cameras 3, 4 to focus an image component PT, for example a pipe system C between two plant parts B and D. In order to enable displaying that is more detailed and more meaningful for personnel, a first method step (cf. FIG. 1) involves receiving the video stream data VS (step S1).

Afterward, method steps S2 and S3 involve establishing a relationship between an available three-dimensional (3D) model of the monitored industrial plant 2 or the plant objects or components thereof and the image components of the video stream VS. For this purpose, in step S2, a respective two-dimensional image component PT, as indicated in FIG. 4, is assigned to a plant object of the industrial plant using a three-dimensional model, for example a CAD (computer-aided design) model of the industrial plant 2.

The illustration in FIG. 4 reveals the assignment by way of the dashed arrow. A 3D model of the plant CAD is illustrated diagrammatically on the right-hand side of FIG. 4. In this case, the plant objects A′, B′, C′, D′ present in the three-dimensional model CAD of the plant are provided with object properties. By way of example, detailed CAD data are present as object properties. In this case, the object properties can comprise the size, position, orientation in space and further properties. In the example illustrated in FIG. 4, the image component PT involves pipes C, for example, which run horizontally and have specific flow materials, for example. In this respect, object data that stipulate a permitted surface temperature of the pipes C′, for example, can be retrieved from a further database relating to the function of the industrial plant.

In step S3, a camera property of that video camera 3, 4 which supplied the image component PT in the video stream VS is ascertained as a recording property of the image. For this purpose, the two-dimensional image data PT that reproduce the plant object C, namely the pipe system, are compared with the object properties present in the three-dimensional plant model CAD. From that it is possible to ascertain for example the position and/or orientation or viewing direction of the camera which supplies the image excerpt PT. Furthermore, a zoom factor of the respective camera can be derived from the knowledge of the position and the image excerpt PT.

In this respect, a recording property, in particular like the orientation of the position and the zoom factor of the video camera device can be captured from the two-dimensional video stream data VS.

In step S4, these context data comprising the plant object data and the recording properties are then output together with the video stream.

In this respect, the proposed method supplies image data-based tracking of the monitoring cameras 3, 4 used. The camera movement and the zoom setting of the respective camera can be ascertained in real time, in particular. The computer-implemented evaluation and image processing of the video stream data can take place according to known methods, as mentioned for example in connection with the Cyclicon software mentioned in the introduction. However, other algorithms that recognize a plant object present in a three-dimensional model on the basis of two-dimensional image data are also conceivable. Algorithms that recognize superimposition points for the 3D model in a 2D image are likewise known. Such algorithms, too, can be used here.

The additional method steps or processes indicated in FIG. 2 are carried out in relation to FIG. 3, which shows a cloud-based monitoring system for an industrial plant 2. A preparatory step S10 involves generating one or more video streams with the aid of the video monitoring cameras 3, 4. The video stream data VS indicated diagrammatically on the left in FIG. 4 are fed to a control console computer 6 via a local computing system. The local computing system 5 receives the video stream data VS of the different monitoring cameras 3, 4, for example, and prepares them for being represented on a display. The corresponding data processing steps take place locally, which is indicated by the curly bracket LKL in FIG. 4.

Since the video stream data VS obtained are present without further context, in particular without knowledge of the location of the monitoring camera 3, 4 used, the or specific video stream data VS with additional information can be displayed by way of a suitable terminal for a user USR, for example by way of a tablet computer or a mobile display apparatus 8. A cloud platform 7, for example using Microsoft Azure, with a corresponding software service 10, 11 is configured for this purpose. The cloud computing environment CLD is indicated in a dashed manner in FIG. 4.

A 3D plant model service 10 and an app service 11 for communicative coupling to the user terminal 8 are provided as software services, in particular.

FIG. 3 furthermore shows a database device 9 coupled to the cloud environment CLD via an interface 12. The database 9 comprises corresponding 3D model data for the monitored industrial plant 2. These data may be CAD data. Furthermore, the database 9 may comprise additional information or context data about the plant objects installed in the plant 2. This may be for example the abovementioned information about flow materials of specific pipelines. The corresponding 3D plant model or the 3D model data is/are generated or provided beforehand in step S11. By way of example, such model data are generated in the course of a design or the planning of an industrial plant.

In step S12, the software service 10 instantiates the corresponding three-dimensional plant model on the basis of the 3D model data, for example CAD data, obtained from the database 9. The software service, designated by 11, of the cloud environment 7 then essentially carries out method steps S1, S2, S3 and S4 taken together as processing process S100 in FIGS. 1 and 2. The dashed double-headed arrow shows the communicative coupling of the terminal 8, namely a display device 8 of the user USR, and the software service or the app 11.

FIG. 5 shows a possible embodiment of display states of the terminal 8. The terminal is a display apparatus 8 comprising a display 14, on which video stream data VS are represented, for example. Furthermore, the user terminal 8 implemented as a display device is provided with operating elements 13. By way of the operating elements 13, the user USR, for example by way of a touchscreen function or other haptic elements, can call up context information with respect to the image data VS′ represented on the display 14.

By way of example, the frame such as is represented on the left of the video stream VS in FIG. 4 is reproduced in FIG. 5A. In the meantime, in the cloud environment CLD by way of the software service 11, respective plant object data concerning the plant objects A, B, C, D recognized in the video stream VS are retrieved by the software service 10. Furthermore, these object data are assigned, as has been described with respect to method step S2.

For example, by way of the software service 11 it may be recognized that the pipelines C in the image component represented in a dashed manner have an increased temperature that does not comply with the target temperature. If the represented plant region C is selected by the user, a zoomed-in representation of the region with added or superimposed additional information XYZ, designated by 15, takes place for example as illustrated in FIG. 5B. The additional information 15 may for example represent a warning and indicate to the user a safety event in the monitored plant. Switching back and forth between different cameras is made possible for the user on the basis of the camera information ascertained in method step S3. By virtue of ascertaining the recording properties with regard to the orientation and the zoom setting, this simplifies navigation and selection of the video stream images to be displayed with the aid of the display device 8.

Overall, the proposed monitoring method permits pure video stream data to be enriched with context data such as object properties stored in a 3D model, and tracking of a possible camera pan or zoom. The proposed functionalities and the extended representation of the video image data can be provided via a cloud environment and a cloud service via a suitable user interface of a display apparatus.

Although the present invention has been described in more specific detail on the basis of an example, various modifications may be made. The image components indicated by way of example, namely pipes, may be arbitrary plant components. Furthermore, the monitoring may be influenced by further sensor data, such as recordings from spectral cameras, for example. A further improvement in the monitoring performance may be provided as a result. Instead of the CAD data mentioned for the 3D models, other formats such as OBJ or further formats are also possible.

### REFERENCE SIGNS

1 Plant monitoring system
2 Plant
3 Video camera/monitoring camera
4 Video camera/monitoring camera
5 Local computing device
6 Control console
7 Cloud environment
8 Display device
9 Database
10 3D model
11 App service
12 Interface
13 Operating elements
14 Display
15 Additional information
A, B, C, D Representation of a plant object in the video stream
A′, B′, C′, D′ Plant object with object properties according to 3D model
PT Image component
S1 Receiving a video stream
S2 Assigning 2D image component to plant object according to the 3D model
S3 Determining recording properties
S4 Outputting the video stream data with camera/object properties
S5 Adding the context data to the video stream data
S10 Generating a video stream
S11 Generating a 3D plant model
S12 Instantiating a 3D plant model
VS Video stream
XYZ Context, camera or additional information

1. A method for monitoring an industrial plant comprising plant objects, the method comprising the following steps:
receiving (S1) a video stream (VS) of the plant generated with the aid of a video camera device, wherein the video stream (VS) comprises a temporal sequence of two-dimensional image data;
assigning (S2) two-dimensional image components (PT) of the video stream (VS) to plant objects (A′, B′, C′, D′) with the aid of a three-dimensional (3D) model (CAD) of the plant, in which respective object properties (XYZ) are allocated to the plant objects (A′, B′, C′, D′);
determining (S3) a recording property of the image data depending on the image components (PT) assigned to one or more plant objects (C′) and the respective object property (XYZ), wherein the recording property comprises a position, an orientation and a zoom factor of the video camera device which captures the video stream; and
outputting (S4) the video stream (VS′) together with the determined object properties (XYZ) and recording properties.

2. The method according to claim 1, wherein the industrial plant is arranged on a plant site and the position of the video camera device on the plant site is ascertained.

3. The method according to claim 2, wherein the video camera device has a video capture region which is smaller than the plant site.

4. The method according to claim 1, wherein the video camera device is mounted at an unknown position during the step of receiving the video stream (VS).

5. The method according to claim 1, wherein the object properties (XYZ) comprise a location, a size and/or dimension, an alignment and/or orientation, a list of constituents, material properties and/or surface properties of the plant object (A′, B′, C′, D′).

6. The method according to claim 1, further comprising:
creating (S11) a database which assigns further functional properties and/or context data to the plant objects (A′, B′, C′, D′).

7. The method according to claim 6, wherein the functional properties and/or context data are updated.

8. The method according to claim 1, wherein the assigning (S2) further takes place depending on functional properties of the plant objects (A′, B′, C′, D′).

9. The method according to claim 1, wherein the three-dimensional model is a computer-aided design model of the industrial plant.

10. The method according to claim 1, wherein a dynamic recording property is determined with the aid of a temporal sequence of two-dimensional image components of the video stream (VS).

11. The method according to claim 10, wherein the camera movement and/or zoom speed are/is ascertained in real time.

12. The method according to claim 1, wherein the video stream (VS) does not comprise information data about the recording property, and the recording property is ascertained exclusively by way of a comparison of the assigned two-dimensional image components (PT) and the data of the 3D model (CAD).

13. The method according to claim 1, wherein the 3D model data comprise a position of the video camera device.

14. The method according to claim 1, wherein a zoom factor is ascertained depending on a plurality of temporally successive two-dimensional image data of the video camera device.

15. The method according to claim 1, further comprising:
representing (S5) the video stream (VS) together with the object properties (XYZ) and/or recording properties with the aid of a display device.

16. The method according to claim 1, further comprising:
creating (S12) the three-dimensional (3D) model of the plant, wherein object properties (XYZ) are allocated to the plant objects.

17. The method according to claim 1, further comprising:
transmitting the video stream (VS) to a processing platform;
transmitting the 3D model (CAD) to the processing platform; and
transmitting the determined recording property from the processing platform to a display device;
wherein the processing platform is designed like a cloud service (CLD) and is configured to carry out the steps of assigning (S2) two-dimensional image components and determining (S3) the respective recording property in a computer-implemented manner in a secure processing environment (CLD).

18. The method according to claim 1, further comprising:
receiving a plurality of video streams (VS) from different video camera devices;
wherein the steps of assigning (S2) two-dimensional image components (PT), determining (S3) a respective recording property and outputting (S4) the video stream (VS) take place for each video stream and the associated video camera devices in each case using a respective 3D model (CAD).

19. The method according to claim 18, further comprising:
optionally forwarding one of the plurality of video streams to a processing platform, wherein the processing platform is a cloud service (CLD) and is configured to carry out the steps of assigning (S2) two-dimensional image components and determining (S3) the respective recording property in a computer-implemented manner in a secure processing environment.

20. A computer program product, comprising machine-readable instructions which, when they are processed by one or more processor devices of a processing environment (CLD), cause one or all method steps of the method according to claim 1 to be carried out.

21. An apparatus for carrying out the method according to claim 1, comprising:
a video camera device for generating the video stream (VS) of the industrial plant;
a storage device for providing the three-dimensional (3D) model of the plant, in which respective object properties (XYZ) are allocated to the plant objects (A′, B′, C′, D′);
a processing device for assigning two-dimensional image components (PT) of the video stream (VS) to plant objects with the aid of the 3D model, and for determining the recording property; and
a display device for outputting the video stream (VS) together with the determined object properties and/or recording properties;
wherein the video camera device, the storage device, the processing device and the display device are communicatively coupled to one another.
